(19) United States
(12) Patent Application Publication
(10) Pub. No.: US 2024/0347549 A1
(43) Pub. Date: Oct. 17, 2024

(54) DISPLAY SUBSTRATE AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Yiming SHA, Beijing (CN); Xiping LI, Beijing (CN); Xinghua LI, Beijing (CN); Haibo LI, Beijing (CN); Xiaoyan YANG, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/293,655

(22) PCT Filed: May 19, 2023
(86) PCT No.: PCT/CN2023/095317

§ 371 Date: Jan. 30, 2024

(30) Foreign Application Priority Data
May 31, 2022 (CN) 202210609879.4

(51) Int. Cl. H01L 27/12

(52) U.S. Cl. CPC H01L 27/1244; H01L 27/1222

(57) ABSTRACT

A display substrate includes a substrate, a reflective layer, a plurality of first signal lines, and an active layer that are stacked in sequence. The active layer includes a plurality of active pairs, and an active pair includes two active patterns. An orthographic projection of an active pattern on the substrate overlaps with an orthographic projection of a first signal line on the substrate, and a portion of the active pair that does not overlap with the first signal line has a gap. An orthographic projection of the reflective layer on the substrate covers at least part of a gap of at least one active pair.

### CROSS-REFERENCE TO RELATED APPLICATIONS

This application is a national phase entry under 35 USC 371 of International Patent Application No. PCT/CN2023/095317, filed on May 19, 2023, which claims priority to Chinese Patent Application No. 202210609879.4, filed on May 31, 2022, which are incorporated herein by reference in their entirety.

### TECHNICAL FIELD

The present disclosure relates to the field of display technologies, and in particular, to a display substrate and a display apparatus.

### BACKGROUND

At present, thin film transistors (TFTs) are the main driving elements of active matrix organic light emitting diodes (AMOLEDs). During the TFTs manufacturing process, short circuits occur between TFTs caused by the processes, resulting in a decrease in the yield of the display substrate.

### SUMMARY

The purpose of the present disclosure is to provide a display substrate and a display apparatus for improving the yield of the display substrate.

To achieve the above purpose, embodiments of the present disclosure provide the following technical solutions.

The embodiments of the present disclosure provide a display substrate. The display substrate includes: a substrate, a reflective layer located on a side of the substrate, a plurality of first signal lines located on a side of the reflective layer away from the substrate and extending along a first direction, and an active layer located on a side of the first signal lines away from the reflective layer. The active layer includes a plurality of active pairs, the active pairs each include two active patterns. A distance between two adjacent active patterns belonging to the same active pair is smaller than a distance between two adjacent active patterns belonging to different active pairs. The active patterns extend along a second direction, the first direction intersecting the second direction. An orthographic projection of an active pattern on the substrate partially overlaps with an orthographic projection of a first signal line on the substrate. A portion of an active pair that does not overlap with the first signal line has a gap. An orthographic projection of the reflective layer on the substrate covers at least part of a gap of at least one active pair.

In some embodiments, the active pattern includes: a first channel and a first connection pattern connected to a first end of the first channel, and the orthographic projection of the first signal line on the substrate covers an orthographic projection of the first channel on the substrate; an orthographic projection of the first connection pattern on the substrate does not overlap with the orthographic projection of the first signal line on the substrate; the gap includes a first sub-gap located between two adjacent first connection patterns in the active pair; and the orthographic projection of the reflective layer on the substrate covers at least one first sub-gap.

In some embodiments, the active pattern further includes a second connection pattern connected to a second end of the first channel; the second connection pattern and the first connection pattern are arranged opposite to each other and are located on two sides of the first signal line; an orthographic projection of the second connection pattern on the substrate does not overlap with the orthographic projection of the first signal line on the substrate; the gap further includes a second sub-gap located between two adjacent second connection patterns in the active pair; and the orthographic projection of the reflective layer on the substrate covers at least one second sub-gap.

In some embodiments, the display substrate further includes a plurality of second signal lines extending along the first direction, the second signal lines and the first signal lines being arranged in the same layer. The active pattern further includes: a second channel, a third connection pattern connected to a third end of the second channel and the second connection pattern, and a fourth connection pattern connected to a fourth end of the second channel away from the third connection pattern; an orthographic projection of a second signal line on the substrate covers an orthographic projection of the second channel on the substrate; the third connection pattern and the fourth connection pattern are located on two sides of the second signal line, and orthographic projections of the third connection pattern and the fourth connection pattern on the substrate do not overlap with the orthographic projection of the second signal line on the substrate; in the same active pair, a distance between two adjacent first connection patterns, a distance between two adjacent second connection patterns, and a distance between two adjacent third connection patterns are all smaller than a distance between two adjacent fourth connection patterns; the gap further includes a third sub-gap located between two adjacent third connection patterns in the active pair; and the orthographic projection of the reflective layer on the substrate covers at least part of at least one third sub-gap.

In some embodiments, the reflective layer includes a plurality of reflective patterns, and an orthographic projection of a single reflective pattern on the substrate covers at least part of a gap of a single active pair.

In some embodiments, at least two of the reflective patterns are connected to each other and are of an integral structure.

In some embodiments, a material of the active layer includes metal oxide.

In some embodiments, a reflectivity of the reflective layer is greater than or equal to 85%.

In some embodiments, a light absorption coefficient of the reflective layer is in a range of 1.0 to 2.0, inclusive.

In some embodiments, a material of the reflective layer includes at least one of aluminum, copper or molybdenum.

In some embodiments, the display substrate further includes a plurality of pixel circuits; a pixel circuit includes a compensation transistor; the compensation transistor includes the first channel and a first gate pattern; and the first gate pattern and the first signal line are connected to each other and are of an integral structure.

In some embodiments, the display substrate further includes the plurality of pixel circuits; the pixel circuit includes a first reset transistor, a first electrode of the first reset transistor is electrically connected to a first electrode of the compensation transistor, and the first reset transistor includes the second channel and a second gate pattern.

The second gate pattern and the second signal line are connected to each other and are of an integral structure.

In some embodiments, the pixel circuit further includes: a writing transistor, a driving transistor, a second reset transistor, a first light-emitting control transistor, a second light-emitting control transistor, and a storage capacitor; a gate of the writing transistor is coupled to a first scan signal line, a first electrode of the writing transistor is coupled to a data signal line, and a second electrode of the writing transistor is coupled to a first node; a gate of the driving transistor is coupled to a second node, a first electrode of the driving transistor is coupled to the first node, and a second electrode of the driving transistor is coupled to a third node; a second electrode of the compensation transistor is coupled to the third node; a gate of the first light-emitting control transistor is coupled to an enable signal line, a first electrode of the first light-emitting control transistor is coupled to a voltage signal line, and a second electrode of the first light-emitting control transistor is coupled to the first node; a gate of the second light-emitting control transistor is coupled to the enable signal line, a first electrode of the second light-emitting control transistor is coupled to the third node, and a second electrode of the second light-emitting control transistor is coupled to a fourth node; a second electrode of the first reset transistor is coupled to a first initialization signal line; a gate of the second reset transistor is coupled to a first reset signal line, a first electrode of the second reset transistor is coupled to a second initialization signal line, and a second electrode of the second reset transistor is coupled to the fourth node; and a first electrode plate of the storage capacitor is coupled to the voltage signal line, and a second electrode plate of the storage capacitor is coupled to the second node.

In some embodiments, the compensation transistor and the first reset transistor are oxide transistors, and the writing transistor, the driving transistor; and the second reset transistor, the first light-emitting control transistor and the second light-emitting control transistor are low temperature polysilicon transistors.

The embodiments of the present disclosure further provide a display apparatus, and the display apparatus includes the display substrate as described in any of the above embodiments.

The display substrate and the display apparatus provided in the present disclosure have the following beneficial effects.

In the display substrate provided in the present disclosure, by providing the reflective layer, the orthographic projection of the reflective layer on the substrate covers the at least part of the gap of the at least one active pair. Therefore, when forming the active patterns in the same active pair, part of light irradiating the reflective layer from opening patterns of a mask is reflected, and part of the reflected light is directed toward photoresist at a position corresponding to the at least part of the gap, which increases the amount of light irradiated to the photoresist at the position corresponding to the at least part of the gap and intensifies the exposure of the photoresist at the position. As a result, after the photoresist is exposed and developed, photoresist between two photoresist patterns is completely removed, and when an active film is etched to form the active patterns using the photoresist patterns as a mask, the active film can be more fully etched, which avoids residual active film material between the two active patterns in the active pair, and reduces the probability of short circuit between the two active patterns in the active pair. Thus, it is more conducive to improving the yield of the display substrate.

Beneficial effects that can be achieved by the display apparatus provided in some embodiments of the present disclosure are the same as the beneficial effects that can be achieved by the display substrate provided in some of the above embodiments, and details will not be repeated here.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display substrate, in accordance with some embodiments of the present disclosure;

FIG. 3A is an equivalent diagram of a pixel driving circuit and a light-emitting device, in accordance with some embodiments of the present disclosure;

FIG. 3B is a structural diagram of a display substrate, in accordance with some embodiments of the present disclosure;

FIG. 4 is a structural diagram of a display substrate, in accordance with some embodiments of the present disclosure;

FIG. 5A is a schematic diagram showing a step of exposing photoresist in a process of forming an active pattern, in accordance with some embodiments of the present disclosure;

FIG. 5B is a schematic diagram showing an exposed and developed photoresist in a process of forming an active pattern, in accordance with some embodiments of the present disclosure;

FIG. 6A is a top view of some film layers in a display substrate, in accordance with some embodiments of the present disclosure;

FIG. 6B is a schematic diagram showing a step of exposing photoresist in a process of forming an active pattern, in accordance with some other embodiments of the present disclosure;

FIG. 6C is a schematic diagram showing an exposed and developed photoresist in a process of forming an active pattern, in accordance with some other embodiments of the present disclosure;

FIG. 6D is a partial diagram of a display substrate, in accordance with some embodiments of the present disclosure;

FIG. 6E is a partial diagram of some film layers in a display substrate, in accordance with some embodiments of the present disclosure;

FIG. 7A is a structural diagram of still another display substrate, in accordance with some embodiments of the present disclosure;

FIG. 7B is a structural diagram of still another display substrate, in accordance with some embodiments of the present disclosure;

FIG. 7C is a structural diagram of still another display substrate, in accordance with some embodiments of the present disclosure;

FIG. 7D is a structural diagram of still another display substrate, in accordance with some embodiments of the present disclosure;

FIG. 8A is a schematic diagram showing a step of exposing photoresist in a process of forming an active pattern, in accordance with some other embodiments of the present disclosure;

FIG. 8B is a schematic diagram showing an exposed and developed photoresist in a process of forming an active pattern, in accordance with some other embodiments of the present disclosure; and

FIG. 9 is a schematic diagram showing a step of exposing photoresist in a process of forming an active pattern, in accordance with some other embodiments of the present disclosure.

### DETAILED DESCRIPTION

The technical solutions in some embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise”, “comprises”, “comprising”, “include”, “includes”, and “including” are construed as an open and inclusive meaning, i.e., “included, but not limited to”. In the description of the specification, the term such as “one embodiment”, “some embodiments”, “exemplary embodiments”, “example” or “some examples” is intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

In the description of some embodiments, the term “coupled” and extensions thereof may be used. For example, the term “coupled” may be used in the description of some embodiments to indicate that two or more components are in direct physical or electrical contact with each other. The embodiments disclosed herein are not necessarily limited to the context herein.

The phrase “A and/or B” includes the following three combinations: only A, only B, and a combination of A and B.

The phrase “configured to” used herein means an open and inclusive expression, which does not exclude devices that are configured to perform additional tasks or steps.

In addition, the phrase “based on” used herein is meant to be open and inclusive, since a process, step, calculation or other action that is “based on” one or more of the stated conditions or values may, in practice, be based on additional conditions or values exceeding those stated.

Herein, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

Exemplary embodiments are described herein with reference to segmental views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the areas shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

In circuit structures (e.g., a pixel circuit) provided in embodiments of the present disclosure, transistors used in the pixel circuit may be thin film transistors (TFTs), metal oxide semiconductor (MOS) transistors, or other switching devices with same properties, and the embodiments of the present disclosure are described by taking the thin film transistors as an example.

In the thin film transistors employed in the circuit structures provided in the embodiments of the present disclosure, a first electrode of each thin film transistor is one of a source and a drain, and a second electrode of each thin film transistor is the other one of the source and the drain. Since the source and the drain of the transistor may be symmetrical in structure, the source and the drain thereof may be indistinguishable in structure. That is, there may be no difference in structure between the first electrode and the second electrode of the transistor in the embodiments of the present disclosure. For example, in a case where the transistor is a P-type transistor, the first electrode of the transistor is the source, and the second electrode of the transistor is the drain. As another example, in a case where the transistor is an N-type transistor, the first electrode of the transistor is the drain, and the second electrode of the transistor is the source.

In the circuit structure provided in the embodiments of the present disclosure, the first node, the second node, etc. do not represent actual components, but rather represent junction points of relevant couplings in a circuit diagram. That is, these nodes are nodes equivalent to junction points of relevant couplings in the circuit diagram.

Herein, the P-type transistor may be turned on under control of a low-level signal, and the N-type transistor may be turned on under control of a high-level signal.

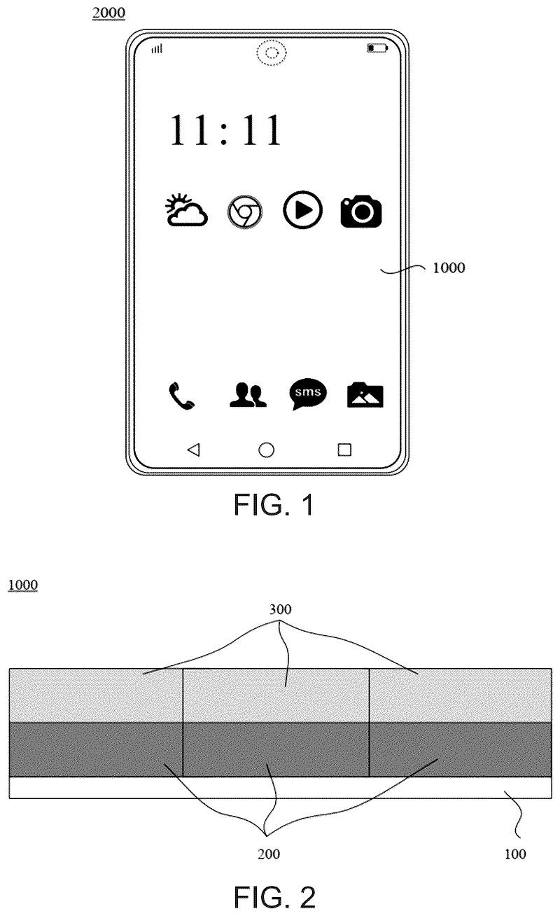

As shown in FIG. 1, some embodiments of the present disclosure provide a display apparatus 2000, and the display apparatus 2000 includes a display substrate 1000.

In some examples, the display apparatus 2000 may be, for example, an organic light-emitting diode (OLED) display apparatus.

For example, the display apparatus 2000 further includes a frame, a display driver integrated circuit (IC), and other electronic components.

For example, the display apparatus 2000 may be any device that displays videos or still images. More specifically, it is expected that the display apparatus in the embodiments may be implemented in or associated with various electronic devices. The various electronic devices may include (but is not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry) etc.

In some examples, as shown in FIG. 2, the display substrate 1000 includes: a substrate 100, a plurality of pixel circuits 200 disposed on a side of the substrate 100, a plurality of light-emitting devices 300 disposed on a side of the plurality of pixel circuits 200 away from the substrate 100.

For example, the substrate 100 may be a flexible substrate or a rigid substrate.

For example, when the substrate 100 is the flexible substrate, the substrate 100 may be made of dimethylsiloxane, polyimide (PI), polyethylene terephthalate (PET), or other high elastic materials.

As another example, when the substrate 100 is the rigid substrate, the substrate 100 may be made of glass or the like.

In some examples, the plurality of pixel circuits 200 may be coupled to the plurality of light-emitting devices 300 in one-to-one correspondence. In some other examples, a single pixel circuit 200 may be coupled to multiple light-emitting devices 300; or, multiple pixel circuits 200 may be coupled to a single light-emitting device 300.

In the present disclosure, the structure of the display substrate 1000 will be schematically described below by taking an example in which a single pixel circuit 200 is coupled to a single light-emitting device 300.

For example, in the display substrate 1000, the pixel circuit 200 may generate a driving signal. Each light-emitting device 300 can emit light under driven of a corresponding pixel circuit 200. Light emitted by the plurality of light-emitting devices 300 cooperates with each other, so that the display substrate 1000 realizes the display function.

For example, the light-emitting device 300 may be an OLED.

In some examples, the structure of the pixel circuit 200 varies, which may be set according to practical needs. For example, the pixel circuit 200 may be of a structure such as “6T1C,” “7T1C,” “6T2C,” or “7T2C”. Here, “T” represents a thin film transistor, a number preceding “T” represents the number of thin film transistors, “C” represents a storage capacitor, and a number preceding “C” represents the number of storage capacitors.

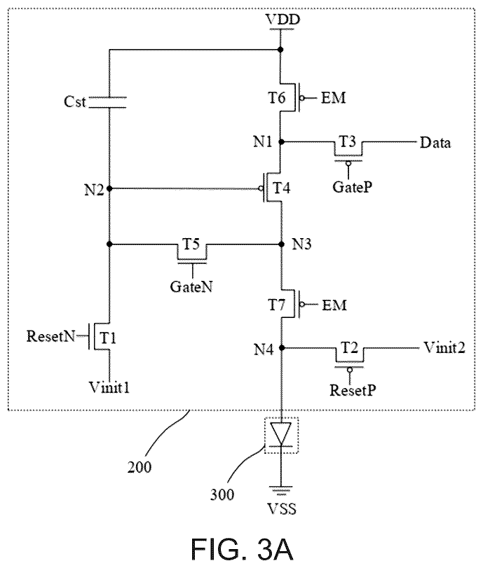

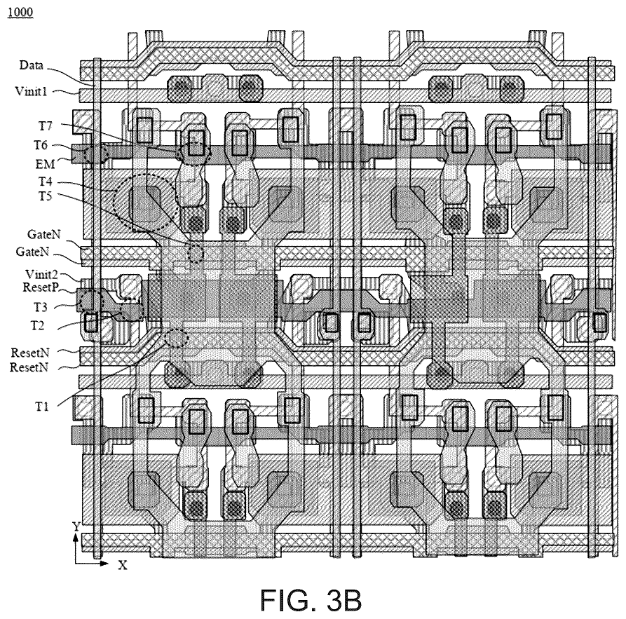

For example, the present disclosure will be described by taking an example in which the structure of the pixel circuit 200 is a “7T1C” structure. FIG. 3A shows an equivalent circuit diagram of a pixel circuit 200 and a light-emitting device 300.

It can be understood that during the operation process of the pixel circuit 200, different signal lines are required to provide corresponding electrical signals for the pixel circuit 200.

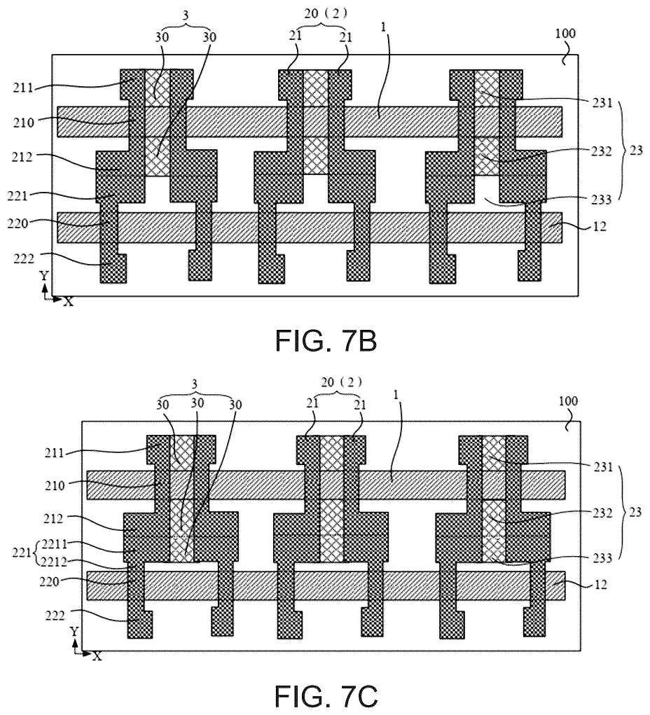

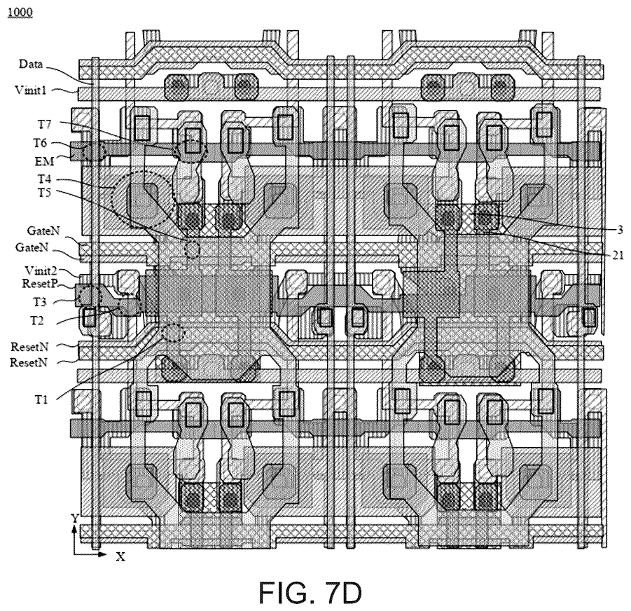

For example, as shown in FIGS. 3B and 7D, the display substrate 1000 includes: a plurality of first scan signal lines GateP, a plurality of second scan signal lines GateN, a plurality of data signal lines Data, and a plurality of first reset signal lines ResetP, a plurality of second reset signal lines ResetN, a plurality of voltage signal lines VDD, a plurality of first initialization signal lines Vinit1, a plurality of second initialization signal lines Vinit2, and a plurality of enable signal lines EM. The first scan signal lines GateP are used to transmit first scan signals, the second scan signal lines GateN are used to transmit second scan signals, the data signal lines Data are used to transmit data signals, and the first reset signal lines ResetP are used to transmit first reset signals, the second reset signal lines ResetN are used to transmit second reset signals, the voltage signal lines VDD are used to transmit voltage signals, the first initialization signal lines Vinit1 are used to transmit first initialization signals, the second initialization signal lines Vinit2 are used to second initialization signals, and the enable signal lines EM are used to transmit enable signals.

For example, the plurality of first scan signal lines GateP, the plurality of second scan signal lines GateN, the plurality of first reset signal lines ResetP, the plurality of second reset signal lines ResetN, the plurality of voltage signal lines VDD, the plurality of first initialization signal lines Vinit1, the plurality of second initialization signal lines Vinit2, and the plurality of enable signal lines EM may all extend along a first direction X, and the plurality of data signal lines Data may extend along a second direction Y.

For example, the display substrate 1000 further includes: a plurality of common voltage signal lines VSS, and the common voltage signal lines VSS are used to transmit common voltages.

For example, as shown in FIG. 3A, the pixel circuit 200 includes: a first reset transistor T1, a second reset transistor T2, a writing transistor T3, a driving transistor T4, a compensation transistor T5, a first light-emitting control transistor T6, a second light-emitting control transistor T7, and a storage capacitor Cst.

For example, as shown in FIG. 3A, a gate of the first reset transistor T1 is coupled to the second reset signal line ResetN, a first electrode of the first reset transistor T1 is coupled to the second node N2, and a second electrode of the first reset transistor T1 is coupled to the first initialization signal line Vinit1. The first reset transistor T1 is configured to be turned on under control of the second reset signal transmitted by the second reset signal line ResetN, and transmit the first initialization signal received at the first initialization signal line Vinit1 to the second node N2 to reset the second node N2.

For example, as shown in FIG. 3A, a gate of the second reset transistor T2 is coupled to the first reset signal line ResetP, a first electrode of the second reset transistor T2 is coupled to the second initialization signal line Vinit2, and a second electrode of the second reset transistor T2 is coupled to the fourth node N4, that is, to the light-emitting device 300. The second reset transistor T2 is configured to be turned on under control of the first reset signal transmitted by the first reset signal line ResetP, and transmit the second initial signal received at the second initial signal line Vinit2 to the fourth node N4 to reset the fourth node N4.

For example, as shown in FIG. 3A, a gate of the writing transistor T3 is coupled to the first scan signal line GateP, a first electrode of the writing transistor T3 is coupled to the data signal line Data, and a second electrode of the writing transistor T3 is coupled to the first node N1, that is, to a first electrode of the driving transistor T4. The writing transistor T3 is configured to be turned on under control of the first scan signal transmitted by the first scan signal line GateP, and transmit the data signal received at the data signal line Data to the first node N1.

For example, as shown in FIG. 3A, a gate of the driving transistor T4 is coupled to the second node N2, a first electrode of the driving transistor T4 is coupled to the first node N1, and a second electrode of the driving transistor T4 is coupled to the third node N3. The driving transistor T4 is configured to be turned on under control of a voltage of the second node N2, and transmit an electrical signal (e.g., the data signal) from the first node N1 to the third node N3.

For example, as shown in FIG. 3A, a gate of the compensation transistor T5 is coupled to the second scan signal line GateN, and a first electrode of the compensation transistor T5 is coupled to the second node N2, that is, to the gate of the driving transistor T4; a second electrode of the compensation transistor T5 is coupled to the third node N3, that is, to the second electrode of the driving transistor T4; and the compensation transistor T5 is configured to be turned on under control of the second scan signal transmitted by the second scan signal line GateN, and transmit an electrical signal (e.g., the data signal) from the third node N3 to the second node N2.

For example, as shown in FIG. 3A, a gate of the first light-emitting control transistor T6 is coupled to the enable signal line EM, a first electrode of the first light-emitting control transistor T6 is coupled to the voltage signal line VDD, and a second electrode of the first light-emitting control transistor T6 is coupled to the first node N1. The first light-emitting control transistor T6 is configured to be turned on under control of the enable signal transmitted by the enable signal line EM, and transmit the voltage signal received at the voltage signal line VDD to the first node N1.

For example, as shown in FIG. 3A, a gate of the second light-emitting control transistor T7 is coupled to the enable signal line EM, and a first electrode of the second light-emitting control transistor T7 is coupled to the third node N3, and a second electrode of the second light-emitting control transistor T7 is coupled to the fourth node N4. The second light-emitting control transistor T7 is configured to be turned on under the control of the enable signal transmitted by the enable signal line EM, and transmit the electrical signal (e.g., the voltage signal) from the third node N3 to the fourth node N4.

For example, as shown in FIG. 3A, a first electrode plate of the storage capacitor Cst is coupled to the voltage signal line VDD, and a second electrode plate of the storage capacitor Cst is coupled to the second node N2.

For example, the operation process of the pixel circuit 200 includes a reset phase, a data writing and compensation phase, and a light-emitting phase.

For example, in the reset phase, the first reset transistor T1 is turned on under the control of the second reset signal transmitted by the second reset signal line ResetN, and transmits the first initialization signal to the second node N2 to reset the second node N2. Since the second node N2 is coupled to the second electrode plate of the storage capacitor Cst, the gate of the driving transistor T4, and the first electrode of the compensation transistor T5, when the second node N2 is reset, the second electrode plate of the storage capacitor Cst, the gate of the driving transistor T4, and the first electrode of the compensation transistor T5 can be reset synchronously. The driving transistor T4 may be turned on under control of the first initialization signal. The second reset transistor T2 is turned on under the control of the first reset signal transmitted by the first reset signal line ResetP. The second reset transistor T2 transmits the second initialization signal to the fourth node N4 to reset the fourth node N4. Since the fourth node N4 is coupled to the anode of the light-emitting device 300, when the fourth node N4 is reset, the anode of the light-emitting device 300 can be reset synchronously.

For example, in the data writing and compensation phase, the writing transistor T3 is turned on under the control of the first scan signal transmitted by the first scan signal line GateP, and the compensation transistor T5 is turned on under the control of the second scan signal transmitted by the second scan signal line GateN. The writing transistor T3 transmits the data signal to the first node N1, and the driving transistor T4 transmits the data signal from the first node N1 to the third node N3. The compensation transistor T5 transmits the data signal from the third node N3 to the second node N2, so as to charge the driving transistor T4 until the compensation of the threshold voltage of the driving transistor T4 is completed.

For example, in the light-emitting phase, the first light-emitting control transistor T6 and the second light-emitting control transistor T7 are turned on simultaneously under the enable signal. The first light-emitting control transistor T6 transmits the voltage signal to the first node N1. The driving transistor T4 transmits the voltage signal from the first node N1 to the third node N3. The second light-emitting control transistor T7 transmits the voltage signal from the third node N3 to the fourth node N4.

The light-emitting device 300 emits light due to the voltage signal from the fourth node N4 and the common voltage from the common voltage line VSS.

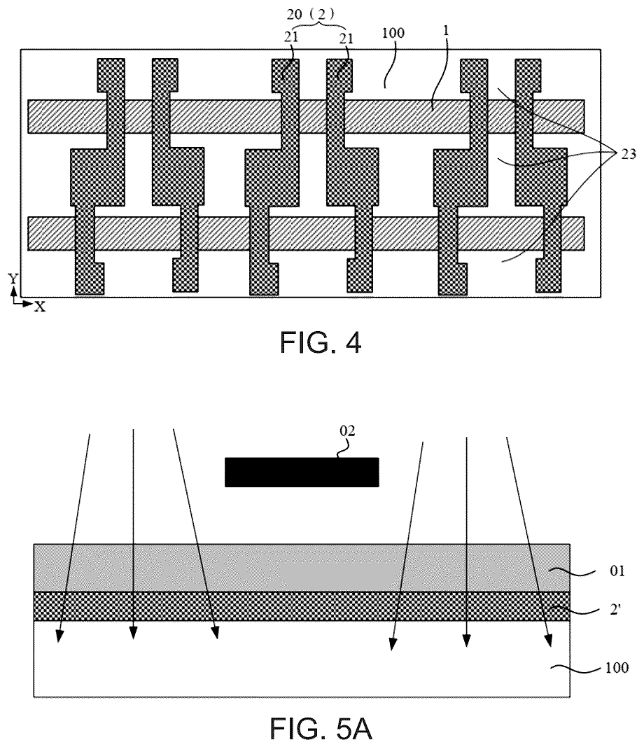

In some examples, as shown in FIG. 4, the display substrate 1000 includes: a plurality of first signal lines 1 located on the side of the substrate 100 and extending along the first direction X, and an active layer 2 located on a side of the first signal lines 1 away from the substrate 100.

In some examples, a first insulation layer is provided between the first signal lines 1 and the active layer 2. The first insulating layer is used to electrically insulate the first signal lines 1 and the active layer 2.

A material of the first insulating layer includes any of inorganic insulating materials of silicon nitride, silicon oxynitride and silicon oxide, and the present disclosure is not limited thereto.

In some examples, as shown in FIG. 4, the active layer 2 includes a plurality of active pairs 20, and the active pair 20 includes two active patterns 21.

For example, a distance between two adjacent active patterns 21 belonging to the same active pair 20 is smaller than a distance between two adjacent active patterns 21 belonging to different active pairs 20.

It should be noted that the “distance between two adjacent active patterns 21 of the same active pair 20” refers to: the minimum distance between two adjacent active patterns 21 included in the same active pair 20.

For example, the active patterns 21 extend along the second direction Y. An orthographic projection of the active pattern 21 on the substrate 100 partially overlaps with an orthographic projection of the first signal line 1 on the substrate 100, and a portion of the active pair 20 that does not overlap with the first signal line 1 has a gap 23.

For example, the second direction Y and the first direction X intersect. An included angle between the first direction X and the second direction Y may be set according to practical needs. For example, the included angle between the first direction X and the second direction Y is 85°, 88° or 90°.

For example, the first signal lines 1 extend along the first direction X, and the active patterns 21 extend along the second direction Y. Since the second direction Y intersects the first direction X, there are overlapping patterns at intersections of orthographic projections of the first signal lines 1 on the substrate 100 and orthographic projection of the active patterns 21 on the substrate 100. Portions of the first signal lines 1 located in the overlapping patterns constitute gate patterns of part of transistors, and portions of the active patterns 21 connected to the overlapping patterns constitute first electrodes or second electrodes of part of transistors.

In some examples, when forming the active patterns 21, the following steps can be performed: 1. deposit an active film; 2. coat the active film with photoresist; 3. expose and develop the photoresist to form photoresist patterns; 4. etch the active film using the photoresist pattern as a mask to form the active patterns; 5. remove the photoresist patterns.

For example, a photoresist completely retained part and a photoresist completely removed part are formed through processes such as exposure and development, and the photoresist completely removed part is removed to obtain a photoresist pattern.

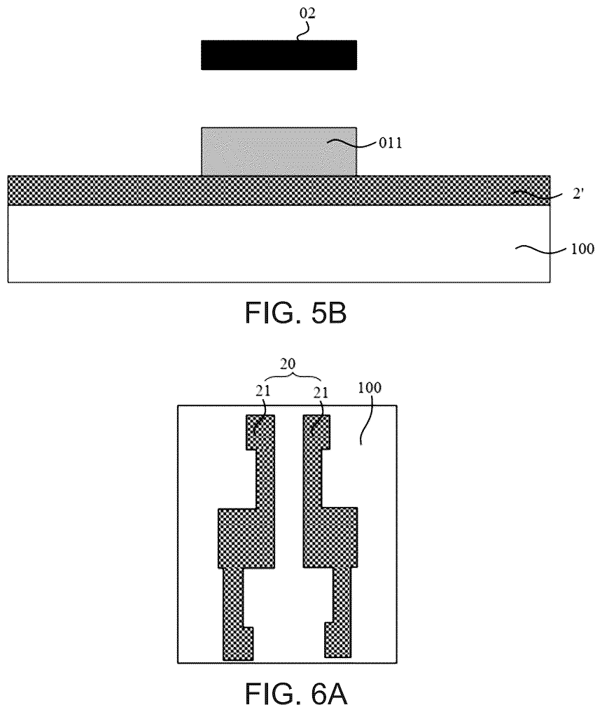

For example, as shown in FIGS. 5A and 5B, FIG. 5A is a schematic diagram of the photoresist 01 being exposed, and FIG. 5B is a schematic diagram of the photoresist 01 after being exposed and developed.

For example, the mask 02 includes a plurality of opening patterns. Light is incident onto the photoresist 01 through the plurality of opening patterns to expose and develop the photoresist 01. The photoresist 01 at positions corresponding to the plurality of opening patterns is completely removed, and the photoresist at other positions is retained, so that the photoresist patterns 011 are obtained. Therefore, when etching the active film 2′, portions of the active film 2′ at the positions corresponding to the plurality of opening patterns are etched to form the active patterns 21.

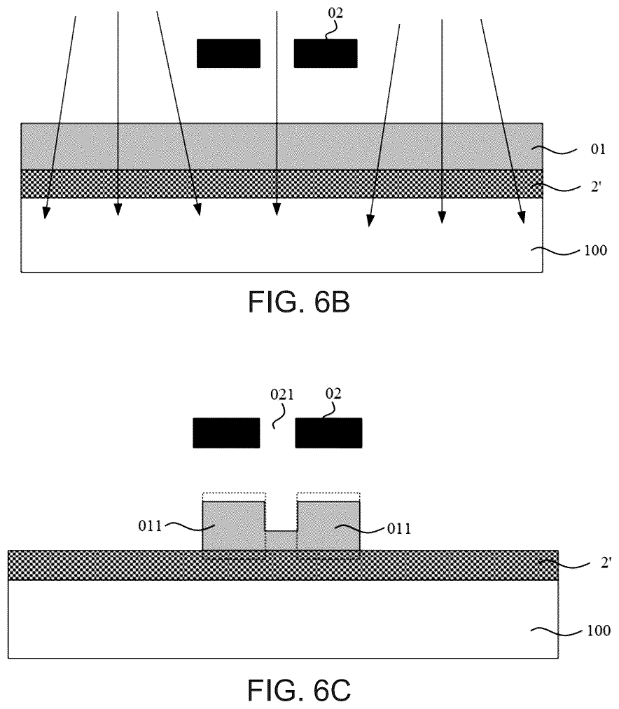

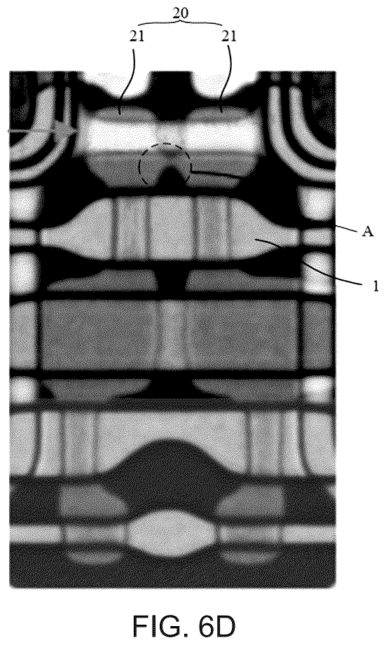

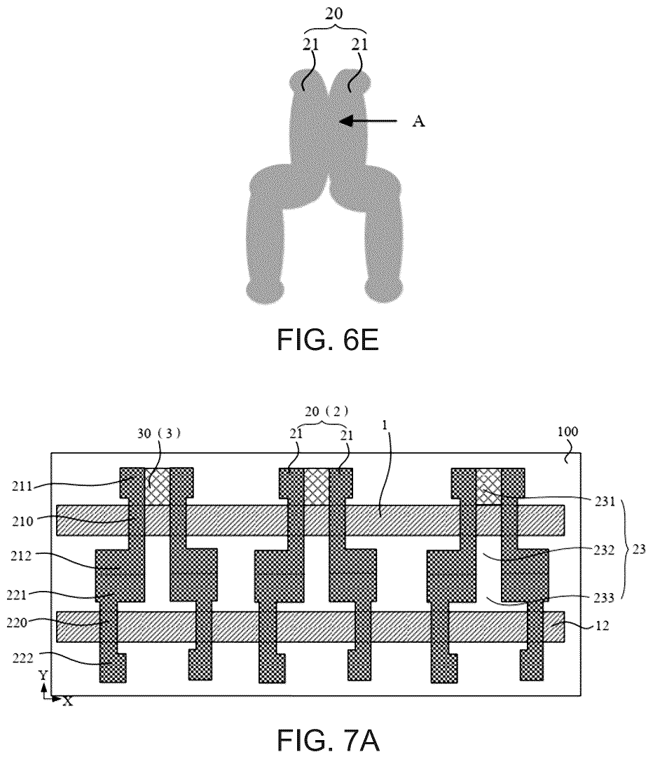

In one implementation, the pixels per inch (PPI) is high, resulting in a small distance between the two active patterns 21 included in the active pair 20, which is shown in FIG. 6A as an example.

For example, as shown in FIGS. 6B to 6E, FIG. 6B is a schematic diagram of the photoresist 01 being exposed; FIG. 6C is a schematic diagram of the photoresist 01 after being exposed and developed; and FIGS. 6D and 6E are partial views of the display substrate 1000.

Since the distance between the two active patterns 21 included in the active pair 20 is small, in the process of forming the active patterns 21, two photoresist patterns 011 that are formed after the photoresist 01 is exposed and developed have a small distance therebetween.

On this basis, when the photoresist 01 is exposed and developed, a width of the opening pattern 021 of the mask 02 is small, which results in a small amount of light irradiating the photoresist 01 through the opening pattern 021. Therefore, the photoresist 01 at the position corresponding to the opening pattern 021 is not completely removed (as shown in FIG. 6C). When the active film 2′ is etched to form the active patterns 21, due to the residue of the photoresist 01 between the two active patterns 21, the active film 2′ is not sufficiently etched at the position between the two active patterns 21. As a result, the active film is remained at this position, which causes a short circuit problem between the two active patterns 21 in the active pair 20.

For example, as shown in FIGS. 6D and 6E, at position A, the active film is not sufficiently etched, and there is active film residue.

In light of this, the display substrate 1000 provided in some embodiments of the present disclosure further includes a reflective layer 3 located between the substrate 100 and the first signal lines 1, as shown in FIGS. 7A to 7C.

In some examples, a second insulating layer is provided between the first signal lines 1 and the reflective layer 3. The second insulating layer is used to electrically insulate the first signal lines 1 and the reflective layer 3.

For example, a material of the second insulating layer includes any of inorganic insulating materials of silicon nitride, silicon oxynitride and silicon oxide, and the present disclosure is not limited thereto.

In some examples, an orthographic projection of the reflective layer 3 on the substrate 100 covers at least part of a gap 23 of at least one active pair 20.

It should be noted that the description that “an orthographic projection of the reflective layer 3 on the substrate 100 covers at least part of a gap 23 of at least one active pair 20” includes various situations: the orthographic projection of the reflective layer 3 on the substrate 100 covers a part of the gap 23 of the at least one active pair 20, or completely covers the entire gap 23 of the at least one active pair 20; and the orthographic projection of the reflective layer 3 on the substrate 100 also covers non-gap positions of an active pair 20 in addition to the at least part of the gap 23 of at least one active pair 20.

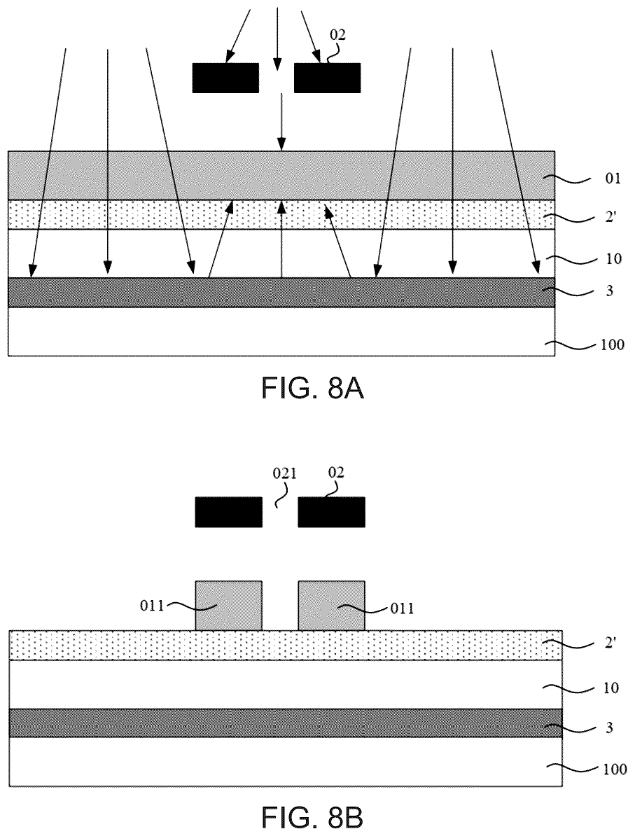

For example, as shown in FIGS. 8A and 8B, FIG. 8A is a schematic diagram of the photoresist 01 being exposed, and FIG. 8B is a schematic diagram of the photoresist 01 after being exposed and developed. Light entering from the opening pattern 021 or other opening patterns of the mask 02 is incident on the reflective layer 3 passing through the active film 2′ and the second insulating layer 10. Part of the light incident on the reflective layer 3 is reflected, and part of the reflected light is directed toward the photoresist 01 corresponding to the position of the opening pattern 021. Then, the photoresist 01 corresponding to the position of the opening pattern 021 is exposed, so that the photoresist 01 corresponding to the position of the opening pattern 021 is completely removed.

In this way, when forming the active patterns 21, part of the light, which is incident on the reflective layer 3 from the opening pattern 021 or other opening patterns of the mask 02, is reflected, and part of the reflected light is directed toward the photoresist 01 corresponding to the position of the opening pattern 021 of the mask 02, thereby increasing the amount of light irradiating the photoresist 01 and intensifying the exposure of the photoresist 01 at this position. Therefore, after the photoresist 01 is exposed and developed, photoresist between two photoresist patterns 011 is completely removed. When the active film 2′ is etched to form the active patterns 21 using the photoresist patterns 011 as a mask, the active film can be etched more fully, which avoids the residual active film material between the two active patterns 21 in the active pair 20, reduces the probability of short circuit between the two active patterns 21 in the active pair 20, and is conducive to improving the yield of the display substrate 1000.

In some examples, the orthographic projection of the reflective layer 3 on the substrate 100 partially overlaps with overlapping portions of the orthographic projections of the active patterns 21 on the substrate 100 and the orthographic projections of the first signal lines 1 on the substrate 100.

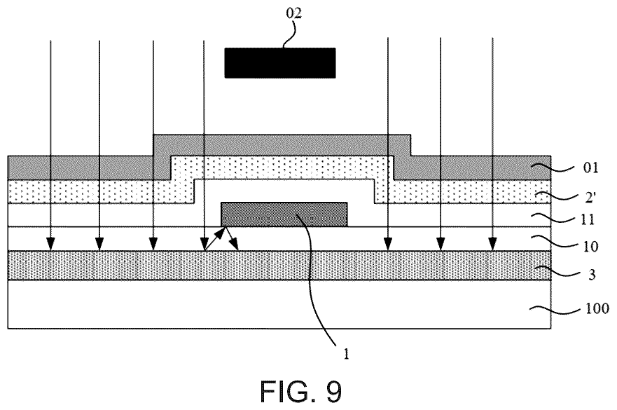

For example, as shown in FIG. 9, light entering from the opening patterns of the mask 02 is incident on the reflective layer 3 passing through the active film 2′, the first insulating layer 11 and the second insulating layer 10. Part of the light incident on the reflective layer 3 is reflected, and part of the reflected light is directed toward the overlapping patterns of the orthographic projections of the first signal lines 1 on the substrate 100 and the orthographic projections of the active patterns 21 on the substrate 100.

For example, a material of the first signal lines 1 includes a conductive metal. The conductive metal may include at least one of aluminum, copper, or molybdenum. Aluminum, copper, and molybdenum each have a high reflectivity. Therefore, the first signal lines 1 have high reflectivity, and light, which is directed toward the overlapping patterns of the orthographic projections of the first signal lines 1 on the substrate 100 and the orthographic projections of the active patterns 21 on the substrate 100, will not pass through the first signal lines 1 to affect the part of the photoresist 01 that needs to be completely retained. When the active patterns 21 are formed through etching, widths of the overlapping patterns of the orthographic projections of the active patterns 21 on the substrate 100 and the orthographic projections of the first signal lines 1 on the substrate 100 will not be affected, thus ensuring the uniformity of the channel sizes of the transistors.

In some embodiments, as shown in FIGS. 7A to 7C, the active pattern 21 includes a first channel 210 and a first connection pattern 211 connected to a first end of the first channel 210.

In some examples, as shown in FIGS. 7A to 7C, the orthographic projection of the first signal line 1 on the substrate 100 covers an orthographic projection of a first channel 210 on the substrate 100. That is, the orthographic projection of the active pattern 21 on the substrate 100 and the orthographic projection of the first signal line 1 on the substrate 100 have the same overlapping pattern. A portion of the active pattern 21 located in the same overlapping pattern is the first channel 210. An orthographic projection of the first connection pattern 211 on the substrate 100 does not overlap with the orthographic projection of the first signal line 1 on the substrate 100.

For example, in the active patterns 21, the first channels 210 constitute the channels of part of transistors, and the first connection patterns 211 connected to the first channels 210 constitute the first electrodes or the second electrodes of part of transistors.

In some examples, as shown in FIGS. 7A to 7C, the gap 23 includes a first sub-gap 231 located between the two adjacent first connection patterns 211 in the active pair 20.

For example, as shown in FIG. 7A, the orthographic projection of the reflective layer 3 on the substrate 100 covers at least one first sub-gap 231.

For example, the orthographic projection of the reflective layer 3 on the substrate 100 may cover one or more first sub-gaps 231. For example, as shown in FIG. 7A, the orthographic projection of the reflective layer 3 on the substrate 100 may cover a plurality of first sub-gaps 231.

In this way, when forming the active patterns 21, part of the light, which is incident on the reflective layer 3 from the opening pattern 021 or other opening patterns of the mask 02, is reflected, and part of the reflected light is directed toward the at least one first sub-gap 231, thereby increasing the amount of light irradiating the photoresist 01 corresponding to a position of the at least one first sub-gap 231 and intensifying the exposure of the photoresist 01. Therefore, after the photoresist 01 is exposed and developed, photoresist corresponding to the position of the at least one first sub-gap 231 is completely removed, and photoresist patterns corresponding to the first connection patterns 211 are formed. When the active film is etched to form the first connection patterns 211 using the photoresist patterns as a mask, the active film corresponding to the at least one first sub-gap 231 can be etched more fully, which avoids the residual active film material at the first sub-gap 231, reduces the probability of short circuit between the two active patterns 21 in the active pair 20 at the first sub-gap 231. Thus, it is conducive to improving the yield of the display substrate 1000.

In some embodiments, the active pattern 21 further includes a second connection pattern 212 connected to a second end of the first channel 210.

In some examples, as shown in FIGS. 7A to 7C, the second connection pattern 212 and the first connection pattern 211 are arranged oppositely and located on two sides of the first signal line 1. An orthographic projection of the second connection pattern 212 on the substrate 100 does not overlap with the orthographic projections of the first signal lines 1 on the substrate 100.

In some examples, the first connection patterns 211 constitute the first electrodes of part of transistors, and the second connection patterns 212 constitute the second electrodes of part of transistors. In some other examples, the first connection patterns 211 constitute the second electrodes of part of transistors, and the second connection patterns 212 constitute the first electrodes of part of transistors. The embodiments of the present disclosure are not limited to thereto.

In some examples, as shown in FIGS. 7A to 7C, the gap 23 further includes a second sub-gap 232 located between the two adjacent second connection patterns 212 in the active pair 20.

For example, as shown in FIG. 7B, the orthographic projection of the reflective layer 3 on the substrate 100 covers at least one second sub-gap 232.

For example, the orthographic projection of the reflective layer 3 on the substrate 100 may cover one or more second sub-gaps 232. For example, as shown in FIG. 7B, the orthographic projection of the reflective layer 3 on the substrate 100 may cover a plurality of second sub-gaps 232.

In this way, when forming the active patterns 21, part of the light, which is incident on the reflective layer 3 from the opening pattern 021 or other opening patterns of the mask 02, is reflected, and part of the reflected light is directed toward the at least one second sub-gap 232, thereby increasing the amount of light irradiating the photoresist 01 and intensifying the exposure of the photoresist 01. Therefore, after the photoresist 01 is exposed and developed, photoresist corresponding to a position of the at least one second sub-gap 232 is completely removed, and photoresist patterns corresponding to the second connection patterns 212 are formed. When the active film is etched to form the second connection patterns 212 using the photoresist patterns as a mask, the active film corresponding to the at least one second sub-gap 232 can be etched more fully, which avoids the residual active film material at the second sub-gap 232, reduces the probability of short circuit between the two active patterns 21 in the active pair 20 at the second sub-gap 232. Thus, it is conducive to improving the yield of the display substrate 1000.

In some embodiments, as shown in FIGS. 7A to 7C, the display substrate 1000 further includes a plurality of second signal lines 12 extending along the first direction X.

In some examples, as shown in FIGS. 7A to 7C, the second signal lines 12 and the first signal lines 1 are arranged in the same layer.

It will be noted that, the “same layer” refers to a layer structure formed by forming a film layer for forming a specific pattern through a same film forming process and then performing a single patterning process using a same mask. Depending on different specific patterns, the patterning process may include exposure processes, development processes or etching processes, the specific patterns in the formed layer structure may be continuous or discontinuous, and these specific patterns may also be at different heights or have different thicknesses. In this way, the second signal lines 12 and the first signal lines 1 may be formed simultaneously, which simplifies the manufacturing process of the display substrate 1000.

In some examples, as shown in FIGS. 7A to 7C, the active pattern 21 further includes: a second channel 220, a third connection pattern 221 connected to a third end of the second channel 220 and the second connection pattern 212, and a fourth connection pattern 222 connected to a fourth end of the second channel 220 away from the third connection pattern 221.

In some examples, as shown in FIGS. 7A to 7C, an orthographic projection of the second signal line 12 on the second substrate 100 covers an orthographic projection of the second channel 220 on the second substrate 100.

In some examples, as shown in FIGS. 7A to 7C, the third connection pattern 221 and the fourth connection pattern 222 are located on two sides of the second signal line 12, and orthographic projections of the third connection pattern 221 and the fourth connection pattern 222 on the substrate 100 do not overlap with the orthographic projection of the second signal line 12 on the substrate 100.

For example, the second channels 220 constitute channels of part of transistors; and the third connection patterns 221 or the fourth connection patterns 222 constitute first electrodes or second electrodes of part of transistors. For example, the third connection patterns 221 constitute the first electrodes of part of transistors, and the fourth connection patterns 222 constitute the second electrodes of part of transistors; alternatively, the third connection patterns 221 constitute the second electrodes of part of transistors, and the fourth connection patterns 222 constitute the first electrodes of part of transistors, which will not be limited in the embodiments of the present disclosure.

In some examples, as shown in FIGS. 7A to 7C, in the same active pair 20, a distance between two adjacent first connection patterns 211, a distance between two adjacent second connection patterns 212 and a distance between two adjacent third connection patterns 221 are all smaller than a distance between two adjacent fourth connection patterns 222.

For example, in the same active pair 20, the distance between two adjacent first connection patterns 211, the distance between two adjacent second connection patterns 212 and the distance between two adjacent third connection patterns 221 may be equal or unequal, which will not be limited in the embodiments of the present disclosure.

For example, as shown in FIGS. 7A to 7C, in the same active pair 20, the distance between two adjacent first connection patterns 211 is equal to the distance between two adjacent second connection patterns 212.

In some examples, as shown in FIGS. 7A to 7C, the gap 23 further includes a third sub-gap 233 located between two adjacent third connection patterns 221 in the active pair 20.

For example, as shown in FIG. 7C, the orthographic projection of the reflective layer 3 on the substrate 100 covers at least part of at least one third sub-gap 233.

It should be noted that the description “the orthographic projection of the reflective layer 3 on the substrate 100 covers at least part of at least one third sub-gap 233” includes: the orthographic projection of the reflective layer 3 on the substrate 100 covers a part of the at least one third sub-gap 233, or the orthographic projection of the reflective layer 3 on the substrate 100 covers the at least one third sub-gap 233, or other situations.

In some examples, as shown in FIG. 7C, the third connection pattern 221 includes a first connection sub-pattern 2211 and a second connection sub-pattern 2212. The first connection sub-pattern 2211 is closer to the second connection pattern 212 than the second connection sub-pattern 2212.

In the same active pair 20, a distance between two adjacent first connection sub-patterns 2211 is smaller than a distance between two adjacent second connection sub-patterns 2212. In this case, the orthographic projection of the reflective layer 3 on the substrate 100 may cover a gap between the two adjacent first connection sub-patterns 2211; or, the orthographic projection of the reflective layer 3 on the substrate 100 covers the gap between the two adjacent first connection sub-patterns 2211 and a gap between the two adjacent second connection sub-patterns 2212.

In this way, when forming the active patterns 21, part of the light, which is incident on the reflective layer 3 from the opening pattern 021 or other opening patterns of the mask 02, is reflected, and part of the reflected light is directed toward the at least one third sub-gap 233, thereby increasing the amount of light irradiating the photoresist 01 and intensifying the exposure of the photoresist 01. Therefore, after the photoresist 01 is exposed and developed, photoresist corresponding to a position of at least part of the at least one third sub-gap 233 is completely removed, and photoresist patterns corresponding to the third connection patterns 221 are formed. When the active film is etched to form the third connection patterns 221 using the photoresist patterns as a mask, the active film corresponding to the at least part of the at least one third sub-gap 233 can be etched more fully, which avoids the residual active film material at the third sub-gap 233, reduces the probability of short circuit between the two active patterns 21 in the active pair 20 at the third sub-gap 233. Thus, it is conducive to improving the yield of the display substrate 1000.

In some embodiments, as shown in FIGS. 7A to 7C, the reflective layer 3 includes a plurality of reflective patterns 30.

In some examples, an orthographic projection of a single reflective pattern 30 on the substrate 100 covers at least part of a gap 23 of a single active pair 20.

It should be noted that the description “an orthographic projection of a single reflective pattern 30 on the substrate 100 covers at least part of a gap 23 of a single active pair 20” includes: the orthographic projection of the single reflective pattern 30 on the substrate 100 covers a part of the gap 23 of the single active pair 20; or, the orthographic projection of the single reflective pattern 30 on the substrate 100 covers the entire gap 23 of the single active pair 20, or other situations.

For example, when the gap 23 includes a first sub-gap 231, a second sub-gap 232 and a third sub-gap 233, an orthographic projection of each reflective pattern 30 on the substrate 100 covers at least one of the first sub-gap 231, the second sub-gap 232, or the third sub-gap 233.

In this embodiment, the reflective layer 3 includes a plurality of reflective patterns 30, and the orthographic projection of a single reflective pattern 30 on the substrate 100 covers at least part of the gap 23 of a single active pair 20. The light incident on the reflective layer 3 is reflected, and part of the reflected light is directed toward at least part of the gap 23, so that the photoresist 01 corresponding to the at least part of the gap 23 is completely removed, and photoresist patterns corresponding to the active patterns 21 are formed. When the active film is etched to form the active patterns 21 using the photoresist patterns as a mask, the active film corresponding to the at least part of the gap 23 can be etched more fully, which avoids the residual active film material at the at least part of the gap 23, reduces the probability of short circuit between the two active patterns 21 in the active pair 20 at the at least part of the gap 23. Thus, it is conducive to improving the yield of the display substrate 1000.

In some embodiments, at least two reflective patterns 30 are connected to each other and are of an integral structure.

For example, the “integral structure” means that two connected patterns are arranged in the same layer, and the two patterns are continuous and not separated. That is, in the embodiments of the present disclosure, at least two reflective patterns 30 are located in the same film layer, and the at least two reflective patterns 30 are connected to each other.

For example, in the embodiments of the present disclosure, at least two reflective patterns 30 are located in the same film layer, and the at least two reflective patterns 30 are connected to each other, and they are continuous and not separated. In this way, the manufacturing process of the display substrate 1000 may be simplified.

In some embodiments, the material of the active layer 2 may include metal oxide.

For example, the metal oxide may be Indium Gallium Zinc Oxide (IGZO) or other metal oxide semiconductor materials.

For example, in the embodiments of the present disclosure, a transistor to which the first channel 210 belongs is a metal oxide thin film transistor. A transistor to which the second channel 220 belongs is a metal oxide thin film transistor. The metal oxide thin film transistor has a low leakage current.

In some embodiments, the reflectivity of the reflective layer 3 is greater than or equal to 85%. For example, the reflectivity of the reflective layer 3 may be 85%, 88%, 91%, 94%, 97%, etc. Therefore, the reflectivity of the reflective layer 3 is large, which can improve the reflection of light irradiating the reflective layer 3. When the orthographic projection of the reflective layer 3 on the substrate 100 covers at least part of the gap 23 of the active pair 20, the amount of light irradiating the photoresist 01 corresponding to a position of the at least part of the gap 23 is increased, and the exposure of the photoresist 01 at this position is intensified. As a result, after the photoresist 01 is exposed and developed, photoresist between two photoresist patterns 011 is completely removed.

In some embodiments, a light absorption coefficient of the reflective layer 3 is in a range of 1.0 to 2.0, inclusive. For example, the light absorption coefficient of the reflective layer 3 is 1.2, 1.4, 1.6, 1.8, 2.0, etc. Therefore, part of the light that is not reflected by the reflective layer 3 or light that is reflected by the first signal lines 1 or the second signal lines 12 and then directed toward the reflective layer 3 will be absorbed by the reflective layer 3.

In some embodiments, the material of the reflective layer 3 includes at least one of aluminum, copper, or molybdenum. Since aluminum, copper, and molybdenum all have high reflectivity, and the reflective layer 3 has a high reflectivity of light, which can improve the reflection of light irradiating the reflective layer 3.

In some embodiments, the compensation transistor T5 in the pixel circuit includes the first channel 210 and the first gate pattern as mentioned above.

In some examples, the first gate pattern and the first signal line 1 are connected to each other and are of an integral structure.

For example, the first gate pattern of the compensation transistor T5 and the first signal line 1 are located in the same film layer, and the first gate pattern and the first signal line 1 are coupled to each other, and they are continuous and not separated. In this way, the manufacturing process of the display substrate 1000 may be simplified. In this case, the first signal line 1 is the second scan signal line GateN, and a signal transmitted by the first signal line 1 is the second scan signal. The compensation transistor T5 may be turned on under the control of the second scan signal transmitted by the second scan signal line GateN.

In some examples, the first connection pattern 211 constitutes the second electrode of the compensation transistor T5, and the second connection pattern 212 constitutes the first electrode of the compensation transistor T5. In this case, the first connection pattern 211 is coupled to the third node, and the second connection pattern 212 is coupled to the second node N2.

In some embodiments, as shown in FIGS. 7A to 7D, the first reset transistor T1 includes the second channel 220 and the second gate pattern as mentioned above.

In some examples, the second gate pattern and the second signal line 12 are connected to each other and are of an integral structure.

For example, the second gate pattern of the first reset transistor T1 and the second signal line 12 are located in the same film layer, and the second gate pattern and the second signal line 12 are coupled to each other, and they are continuous and not separated. In this way, the manufacturing process of the display substrate 1000 may be simplified. In this case, the second signal line 12 is the above-mentioned reset signal line ResetN, and a signal transmitted by the second signal line 12 is the reset signal. The first reset transistor T1 can be turned on under the control of the reset signal transmitted by the reset signal line ResetN.

In some examples, the third connection pattern 221 constitutes the first electrode of the first reset transistor T1, and the fourth connection pattern 222 constitutes the second electrode of the first reset transistor T1. In this case, the third connection pattern 221 is electrically connected to the second connection pattern 212, thereby realizing the electrical connection between the first reset transistor T1 and the compensation transistor T5. The fourth connection pattern 222 is coupled to the first initialization signal line Vinit1.

In some embodiments, the compensation transistor T5 and the first reset transistor T1 are both oxide transistors; and the writing transistor T3, the driving transistor T4, the second reset transistor T2, the first light-emitting control transistor T6, and the second light-emitting control transistor T7 are all low-temperature polycrystalline silicon transistors.

For example, since the oxide transistor has a low leakage current, by setting the first reset transistor T1 as an oxide transistor, it may be possible to reduce the leakage current of the second node N2 through the first reset transistor T1 when the first reset transistor T1 is in an off state after resetting the second node N2, resulting in a good reset effect of the second node N2. By setting the compensation transistor T5 as an oxide transistor, it may be possible to reduce the leakage current of the compensation transistor T5 in the data writing and compensation phase, avoid the leakage current of the second node N2 through the compensation transistor and the first reset transistor, and in turn ensure the compensation effect of the driving transistor T4 and the stability of the voltage of the second node N2, thus improving the display quality of the display substrate 1000. Since the low-temperature polysilicon transistor has high mobility, by setting the driving transistor T4 and other transistors as low-temperature polysilicon transistors, it may be possible to accelerate the charging speed of the storage capacitor, and in turn improve the display quality of the display substrate 1000.

On this basis, the orthographic projection of the reflective layer 3 on the substrate 100 covers at least part of a gap 23 of at least one active pair 21.

For example, as shown in FIG. 7D, the orthographic projection of the reflective layer 3 on the substrate 100 covers the entire gap 23 of the at least one active pair 21. Therefore, when forming the active pairs 21, part of the light, which is incident on the reflective layer 3 from the opening patterns of the mask, is reflected, and part of the reflected light is directed toward photoresist corresponding to positions of the opening patterns of the mask, thereby increasing the amount of light irradiating the photoresist and intensifying the exposure of the photoresist 01 at the positions. Therefore, after the photoresist is exposed and developed, photoresist corresponding to the positions of the gaps 23 is completely removed, and photoresist patterns corresponding to the active pairs 21 are formed. When the active film is etched to form the active pairs 21 using the photoresist patterns as a mask, the active film corresponding to the at least one first sub-gap 231 can be etched more fully, which avoids the residual active film material at the gap 23, reduces the probability of short circuit between the two active patterns 21 in the active pair 20. Thus, it is conducive to improving the yield of the display substrate 1000.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display substrate, comprising:
a substrate;
a reflective layer located on a side of the substrate;
a plurality of first signal lines located on a side of the reflective layer away from the substrate and extending along a first direction; and
an active layer located on a side of the plurality of first signal lines away from the reflective layer, wherein the active layer includes a plurality of active pairs, and the plurality of active pairs each include two active patterns; a distance between two adjacent active patterns belonging to a same active pair is smaller than a distance between two adjacent active patterns belonging to different active pairs;
the active patterns extend along a second direction, the second direction intersecting the first direction;
an orthographic projection of an active pattern in an active pair on the substrate partially overlaps with an orthographic projection of a first signal line on the substrate, and a portion of the active pair that does not overlap with the first signal line has a gap; and
an orthographic projection of the reflective layer on the substrate covers at least part of a gap of at least one active pair.

2. The display substrate according to claim 1, wherein
the active pattern includes: a first channel and a first connection pattern connected to a first end of the first channel, and the orthographic projection of the first signal line on the substrate covers an orthographic projection of the first channel on the substrate; an orthographic projection of the first connection pattern on the substrate does not overlap with the orthographic projection of the first signal line on the substrate;
the gap includes a first sub-gap located between two adjacent first connection patterns in the active pair; and
the orthographic projection of the reflective layer on the substrate covers at least one first sub-gap.

3. The display substrate according to claim 2, wherein
the active pattern further includes a second connection pattern connected to a second end of the first channel; the second connection pattern and the first connection pattern are arranged opposite to each other and are located on two sides of the first signal line;
an orthographic projection of the second connection pattern on the substrate does not overlap with the orthographic projection of the first signal line on the substrate;
the gap further includes a second sub-gap located between two adjacent second connection patterns in the active pair; and
the orthographic projection of the reflective layer on the substrate covers at least one second sub-gap.

4. The display substrate according to claim 3, further comprising: a plurality of second signal lines extending along the first direction, the plurality of second signal lines and the plurality of first signal lines being arranged in the same layer; wherein
the active pattern further includes: a second channel, a third connection pattern connected to a third end of the second channel and the second connection pattern, and a fourth connection pattern connected to a fourth end of the second channel away from the third connection pattern;
an orthographic projection of a second signal line on the substrate covers an orthographic projection of the second channel on the substrate;
the third connection pattern and the fourth connection pattern are located on two sides of the second signal line, and orthographic projections of the third connection pattern and the fourth connection pattern on the substrate do not overlap with the orthographic projection of the second signal line on the substrate;
in the same active pair, a distance between two adjacent first connection patterns, a distance between two adjacent second connection patterns, and a distance between two adjacent third connection patterns are all smaller than a distance between two adjacent fourth connection patterns;
the gap further includes a third sub-gap located between two adjacent third connection patterns in the active pair; and
the orthographic projection of the reflective layer on the substrate covers at least part of at least one third sub-gap.

5. The display substrate according to claim 4, wherein
the reflective layer includes a plurality of reflective patterns, and an orthographic projection of a single reflective pattern on the substrate covers at least part of a gap of a single active pair.

6. The display substrate according to claim 5, wherein
at least two of the plurality of reflective patterns are connected each other and are of an integral structure.

7. The display substrate according to claim 1, wherein
a material of the active layer includes metal oxide.

8. The display substrate according to claim 7, wherein
a reflectivity of the reflective layer is greater than or equal to 85%.

9. The display substrate according to claim 8, wherein
a light absorption coefficient of the reflective layer is in a range of 1.0 to 2.0, inclusive.

10. The display substrate according to claim 9, wherein
a material of the reflective layer includes at least one of aluminum, copper or molybdenum.

11. The display substrate according to claim 4, further comprising a plurality of pixel circuits; wherein
a pixel circuit of the plurality of pixel circuits includes a compensation transistor; the compensation transistor includes the first channel and a first gate pattern; and
the first gate pattern and the first signal line are connected to each other and are of an integral structure.

12. The display substrate according to claim 11, wherein
the pixel circuit further includes a first reset transistor, and a first electrode of the first reset transistor is electrically connected to a first electrode of the compensation transistor;
the first reset transistor includes the second channel and a second gate pattern; and
the second gate pattern and the second signal line are connected to each other and are of an integral structure.

13. The display substrate according to claim 12, wherein
the pixel circuit further includes: a writing transistor, a driving transistor, a second reset transistor, a first light-emitting control transistor, a second light-emitting control transistor, and a storage capacitor;
a gate of the writing transistor is coupled to a first scan signal line, a first electrode of the writing transistor is coupled to a data signal line, and a second electrode of the writing transistor is coupled to a first node;
a gate of the driving transistor is coupled to a second node, a first electrode of the driving transistor is coupled to the first node, and a second electrode of the driving transistor is coupled to a third node;
a second electrode of the compensation transistor is coupled to the third node;
a gate of the first light-emitting control transistor is coupled to an enable signal line, a first electrode of the first light-emitting control transistor is coupled to a voltage signal line, and a second electrode of the first light-emitting control transistor is coupled to the first node;
a gate of the second light-emitting control transistor is coupled to the enable signal line, a first electrode of the second light-emitting control transistor is coupled to the third node, and a second electrode of the second light-emitting control transistor is coupled to a fourth node;
a second electrode of the first reset transistor is coupled to a first initialization signal line;
a gate of the second reset transistor is coupled to a first reset signal line, a first electrode of the second reset transistor is coupled to a second initialization signal line, and a second electrode of the second reset transistor is coupled to the fourth node; and
a first electrode plate of the storage capacitor is coupled to the voltage signal line, and a second electrode plate of the storage capacitor is coupled to the second node.

14. The display substrate according to claim 13, wherein the compensation transistor and the first reset transistor are oxide transistors, and the writing transistor, the driving transistor; and the second reset transistor, the first light-emitting control transistor and the second light-emitting control transistor are low temperature polysilicon transistors.

15. A display apparatus, comprising the display substrate according to claim 1.

16. The display substrate according to claim 5, further comprising a plurality of pixel circuits; wherein
a pixel circuit of the plurality of pixel circuits includes a compensation transistor; the compensation transistor includes the first channel and a first gate pattern; and
the first gate pattern and the first signal line are connected to each other and are of an integral structure.

17. The display substrate according to claim 16, wherein
the pixel circuit further includes a first reset transistor, and a first electrode of the first reset transistor is electrically connected to a first electrode of the compensation transistor;
the first reset transistor includes the second channel and a second gate pattern; and
the second gate pattern and the second signal line are connected to each other and are of an integral structure.

18. The display apparatus according to claim 15, wherein the active pattern includes: a first channel and a first connection pattern connected to a first end of the first channel, and the orthographic projection of the first signal line on the substrate covers an orthographic projection of the first channel on the substrate; an orthographic projection of the first connection pattern on the substrate does not overlap with the orthographic projection of the first signal line on the substrate;
the gap includes a first sub-gap located between two adjacent first connection patterns in the active pair; and
the orthographic projection of the reflective layer on the substrate covers at least one first sub-gap.

19. The display apparatus according to claim 18, wherein the active pattern further includes a second connection pattern connected to a second end of the first channel; the second connection pattern and the first connection pattern are arranged opposite to each other and are located on two sides of the first signal line;
an orthographic projection of the second connection pattern on the substrate does not overlap with the orthographic projection of the first signal line on the substrate;
the gap further includes a second sub-gap located between two adjacent second connection patterns in the active pair; and
the orthographic projection of the reflective layer on the substrate covers at least one second sub-gap.

20. The display apparatus according to claim 19, wherein the display substrate further includes a plurality of second signal lines extending along the first direction, the plurality of second signal lines and the plurality of first signal lines being arranged in the same layer; wherein
the active pattern further includes: a second channel, a third connection pattern connected to a third end of the second channel and the second connection pattern, and a fourth connection pattern connected to a fourth end of the second channel away from the third connection pattern;
an orthographic projection of a second signal line on the substrate covers an orthographic projection of the second channel on the substrate;
the third connection pattern and the fourth connection pattern are located on two sides of the second signal line, and orthographic projections of the third connection pattern and the fourth connection pattern on the substrate do not overlap with the orthographic projection of the second signal line on the substrate;
in the same active pair, a distance between two adjacent first connection patterns, a distance between two adjacent second connection patterns, and a distance between two adjacent third connection patterns are all smaller than a distance between two adjacent fourth connection patterns;
the gap further includes a third sub-gap located between two adjacent third connection patterns in the active pair; and
the orthographic projection of the reflective layer on the substrate covers at least part of at least one third sub-gap.
